(19) United States
(12) Patent Application Publication
(10) Pub. No.: US 2025/0071936 A1
(43) Pub. Date: Feb. 27, 2025

(54) MICROCHANNEL COOLING BLOCK AND COOLING SYSTEM INCLUDING THE SAME

(71) Applicant: HRL LABORATORIES, LLC, Malibu, CA (US)

(72) Inventors: John H. Martin, Vienna, VA (US); David A. Smith, Newbury Park, CA (US); Christopher Roper, Oak Park, CA (US)

(21) Appl. No.: 18/454,755

(22) Filed: Aug. 23, 2023

(51) Int. Cl. H05K 7/20

(52) U.S. Cl. CPC H05K 7/20254

(57) ABSTRACT

A microchannel cooling block includes: a base plate; a microchannel array including a plurality of thermally conductive plates connected to and extending from a surface of the base plate, the thermally conductive plates being aligned so that a highest or second highest thermally conductive axis thereof extends away from the surface of the base plate, adjacent ones of the thermally conductive plates being spaced apart from each other to form a plurality of microchannels between the thermally conductive plates, one of the microchannels being between each adjacent two of the thermally conductive plates; and a manifold connected to the thermally conductive plates, an interior of the manifold being in fluid communication with the microchannels in the microchannel array.

### CROSS-REFERENCE TO RELATED APPLICATIONS

The present disclosure is related to U.S. patent application Ser. No. 16/930,203, filed on Jul. 15, 2020, which issued as U.S. Pat. No. 11,680,756, on Jun. 20, 2023, and which claims priority to U.S. Provisional Patent Application Ser. No. 62/924,031, filed on Oct. 21, 2019, and is related to U.S. patent application Ser. No. 16/784,890, filed on Feb. 7, 2020, which claims priority to U.S. Provisional Patent Application Ser. Nos. 62/828,606 and 62/944,779, filed on Apr. 3, 2019 and Dec. 6, 2019, respectively.

### FIELD

One or more aspects of embodiments of the present disclosure relate to a microchannel cooling block and a cooling system including the microchannel cooling block.

### BACKGROUND

As computer-based systems continue to be central to our daily lives, large-scale servers including many tens, hundreds, or even thousands of individual computer processors (i.e., CPUs) and related components continue to proliferate. Such large-scale server implementations require that size, power, and cooling requirements be met. Often, the cooling requirements for such large-scale server implementations can be a substantial part of the total power requirement and a substantial part of the overall size requirement for the implementation. Size and power considerations also exist for smaller-scale electronics, such as radar systems, microwave and cellular communication systems, etc.

Further, related art cooling systems often utilize specialized refrigerants, such as R134a and R401a, in cooling loops. While modern refrigerants are less environmentally destructive than earlier refrigerants, which were found to cause ozone depletion, they are still environmentally unfriendly when leaked and require specialized handling when used in cooling systems.

### SUMMARY

According to embodiments of the present disclosure, a microchannel cooling block and cooling system including the microchannel cooling block are provided. As explained more fully below, the microchannel cooling block allows for the use of water and water-based coolants for both small and large computer cooling systems. Further, the microchannel cooling block provides exceptional heat transfer while requiring substantially reduced pumping power. The microchannel cooling block includes, in some embodiments, a microchannel array in which thermally conductive sheets are attached to a base plate and spaced apart from each other by very small dimensions, such as about 1 μm to about 500 μm, to form microchannels for a coolant to flow through. To form such small microchannels, the thermally conductive sheets are stacked together with sacrificial spacer sheets, the sheet array is bonded together by an exterior metalized structure, and then the sacrificial spacer sheets are removed (e.g., dissolved) to form the microchannels between the thermally conductive sheets. In this way, the microchannels can be formed to be very small, thereby improving heat transfer and reducing pumping requirements, and because the thermally conductive sheets are supported by an exterior metalized structure, highly thermally conductive but otherwise fragile materials, such as graphite, can be used, further improving heat transfer performance.

A microchannel cooling block, according to an embodiment of the present disclosure, includes: a base plate; a microchannel array including a plurality of thermally conductive plates connected to and extending from a surface of the base plate, the thermally conductive plates being aligned so that a highest or second highest thermally conductive axis thereof extends away from the surface of the base plate, adjacent ones of the thermally conductive plates being spaced apart from each other to form a plurality of microchannels between the thermally conductive plates, one of the microchannels being between each adjacent two of the thermally conductive plates; and a manifold connected to the thermally conductive plates, an interior of the manifold being in fluid communication with the microchannels in the microchannel array.

The conductive plates may include graphite, boron nitride, boron arsenide, diamond, silver, copper, gold, silicon carbide, aluminum, aluminum nitride, tungsten, copper-tungsten (CuW), copper-molybdenum (CuMo), molybdenum, graphene, carbon nanotube, boron nitride nanotube, or a boron nitride platelet composite.

One or more of the thermally conductive plates may be individually clad with a metal.

The thermally conductive plates may have a thickness in a range of 1 μm to 500 μm. The microchannels may have a width in a range of 1 μm to 500 μm.

The base plate may include copper.

The manifold may include a plurality of levels, and each subsequent level may have a greater number of fluid flow passages than a preceding level.

A cooling system, according to an embodiment of the present disclosure, includes: an electronic component; a microchannel cooling block on the electronic component; and a heat exchanger in fluid communication with a manifold of the microchannel cooling block. The microchannel cooling block includes: a base plate; a microchannel array including a plurality of thermally conductive plates connected to and extending from the base plate with a plurality of microchannels between the thermally conductive plates, one of the microchannels being between two adjacent ones of the thermally conductive plates; and the manifold connected to the thermally conductive plates, an interior of the manifold being in fluid communication with the microchannels in the microchannel array.

A coolant flowing between the microchannel cooling block and the heat exchanger may be water based.

The cooling system may further include a primary heat exchanger. The heat exchanger may be a secondary heat exchanger, and the secondary heat exchanger may be configured to transfer heat to the primary heat exchanger.

According to an embodiment of the present disclosure, a method of manufacturing a microchannel cooling block is provided. The method includes: alternately stacking a plurality of thermally conductive sheets and sacrificial spacer sheets to form a thermally conductive sheet-sacrificial spacer sheet array; bonding the thermally conductive sheet-sacrificial spacer sheet array together by forming a metalized outer structure around the thermally conductive sheet-sacrificial spacer sheet array; removing the sacrificial spacer sheets to form a plurality of microchannels between the thermally conductive sheets; and attaching a base plate to one side of the thermally conductive sheets.

The method may further include individually cladding one or more of the thermally conductive sheets.

The thermally conductive sheets may include graphite, boron nitride, boron arsenide, diamond, silver, copper, gold, silicon carbide, aluminum, aluminum nitride, tungsten, copper-tungsten (CuW), copper-molybdenum (CuMo), molybdenum, graphene, carbon nanotube, boron nitride nanotube, or a boron nitride platelet composite.

The method may further include cladding the thermally conductive sheets with a thermally conductive metal.

The sacrificial spacer sheets may be zinc sheets or polylactic acid sheets.

The attaching of the base plate may include electroforming a copper material on the one side of the thermally conductive sheets.

The metalized outer structure may include copper.

The method may further include attaching a manifold to another side of the thermally conductive sheets.

The manifold may include a plurality of levels, and each subsequent level may have a greater number of fluid flow passages than a preceding level.

The thermally conductive sheets may have a thickness in a range of 1 μm to 500 μm, and the sacrificial spacer sheets may have a thickness in a range of 1 μm to 500μm.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

These and other aspects and features of the present disclosure will be further appreciated and better understood with reference to the specification, claims, and appended drawings, in which:

FIG. 1 is a schematic diagram of a cooling loop according to an embodiment of the present disclosure;

FIG. 2 is cross-sectional cutaway view of a microchannel cooling block and manifold according to an embodiment of the present disclosure;

FIG. 3 is a flowchart describing steps of manufacturing the microchannel cooling block shown in FIG. 2;

FIGS. 4A-4F are schematic illustrations of the steps of manufacturing the microchannel cooling block as described in FIG. 3.

FIG. 5 is a schematic diagram of a hierarchical heat exchanger manifold;

FIG. 6A is a photograph of a copper-clad pyrolytic graphite sheet according to an embodiment of the present disclosure;

FIG. 6B is a photograph showing microchannels formed from aligned graphite sheets according to an embodiment of the present disclosure;

FIG. 7 is a graph showing pressure drop within a microchannel of the aligned microchannels according to an embodiment of the present disclosure as a function of total volumetric flow rate; and

FIG. 8 is a graphing showing the thermal resistance of the aligned microchannels according to an embodiment of the present disclosure as a function of required pumping power.

### DETAILED DESCRIPTION

The detailed description set forth below, in connection with the appended drawings, is intended as a description of example embodiments of the present disclosure and is not intended to represent the only forms in which the present disclosure may be embodied. The description sets forth aspects and features of the present disclosure in connection with the illustrated example embodiments. It is to be understood, however, that the same or equivalent aspects and features may be accomplished by different embodiments, and such other embodiments are encompassed within the spirit and scope of the present disclosure. As noted elsewhere herein, like reference numerals in the description and the drawings are intended to indicate like elements. Further, descriptions of features, configurations, and/or other aspects within each embodiment should typically be considered as available for other similar features, configurations, and/or aspects in other embodiments.

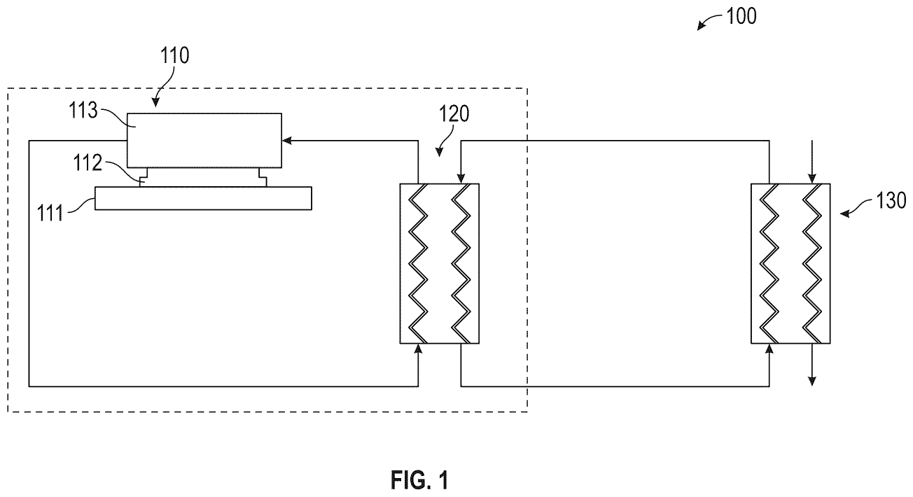

Referring to FIG. 1, a cooling system 100 includes a cooling stack 110, a secondary heat exchanger 120, and a primary heat exchanger 130. The cooling system 100 may represent a facility-level cooling system for various electronic components, such as CPUs (central processing units), GPUs (graphics processing units), systems on a chip (SoCs), field programmable gate arrays (FPGAs), etc. in a server or multiple servers, as an example. The secondary heat exchanger 120 may be one or more heat exchangers, arranged in serial and/or parallel, in a secondary (e.g., rack-level) cooling loop, and the primary heat exchanger 130 may be one or more heat exchangers, arranged in serial and/or parallel, in a primary (e.g., facility-level) cooling loop.

Further, the cooling stack 110 may represent one microchannel cooling block 113 but may represent one or more than one electronic component(s) 112 (e.g., a CPU, GPU, memory chips, etc.) and one or more than one printed circuit board 111 on which the electronic component(s) 112 are arranged. Also, while it is shown in FIG. 1 that the cooling stack 110 includes one microchannel cooling block 113 arranged on one electronic component 112 (e.g., a CPU, GPU, memory chips, etc.), the present disclosure is not limited thereto. In some embodiments, a cooling stack 110 may include one microchannel cooling block 113 arranged on a plurality of adjacent electronic components 112. In other words, a cooling stack 110 may refer to one microchannel cooling block 113 but is not limited to only one electronic component 112.

The secondary cooling loop includes one or more cooling stacks 110 in fluid communication with one or more secondary heat exchangers 120. In various embodiments, a plurality of cooling stacks 110 may be arranged in the same secondary cooling loop. For example, a rack (e.g., a server rack) may include a plurality of cooling stacks 110, each of which is in fluid communication with the same secondary heat exchanger 120. In other cases, however, multiple secondary cooling loops may be implemented together (e.g., in parallel).

The secondary cooling loop may use water or a substantially water-based liquid (e.g., a coolant including water as the primary component by weight or volume) as the coolant. One or more pumps may be included in the secondary cooling loop to move the coolant between the secondary heat exchanger 120 and the cooling stacks 110 to move heat away from the electronic components 112 and to the secondary heat exchanger 120. The secondary cooling loop may be a single-phase cooling loop. In other words, the coolant in the secondary cooling loop may stay in a liquid state (e.g., may not undergo a phase change).

The primary cooling loop includes the primary heat exchanger 130 and moves heat from the secondary heat exchanger(s) 120 to the primary heat exchanger 130 for discharge to the environment. The primary cooling loop may include a plurality of secondary heat exchangers 120 in fluid communication with the primary heat exchanger 130. Similar to the secondary cooling loop, the primary cooling loop may also include pumps to move the coolant through the primary cooling loop. Also, because the primary heat exchanger 130 is exposed to the environment (e.g., the outdoor environment), the coolant in the primary cooling loop may include an ethylene glycol-water mixture to avoid freezing. The primary cooling loop may also be a single-phase cooling loop, and the primary heat exchanger 130 may be a dry air-cooler.

The secondary heat exchanger 120 may exchange heat from the secondary cooling loop to the primary cooling loop via a fluid/fluid interface while the primary heat exchanger 130 may exchange heat from the primary cooling loop to the environment via a fluid/air interface.

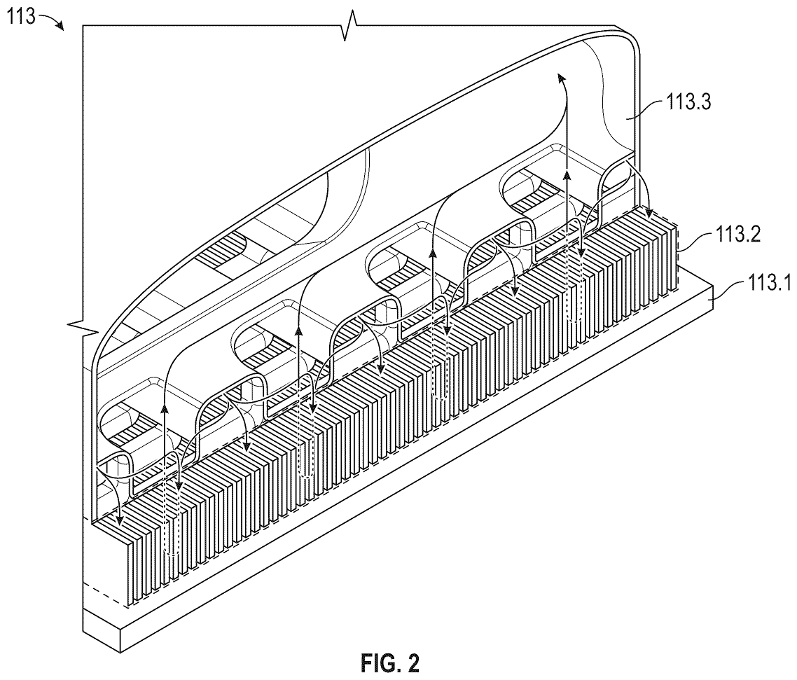

Referring to FIG. 2, the microchannel cooling block 113 shown in FIG. 1 is shown in more detail. The microchannel cooling block 113 includes a base plate 113.1, a microchannel array 113.2 including plurality of aligned microchannels on the base plate 113.1, and a manifold 113.3 on the microchannel array 113.2. As explained in more detail below, the base plate 113.1 is arranged on the electronic component 112 to be cooled, and the manifold 113.3 receives coolant from the secondary cooling loop and discharges heated coolant to the same.

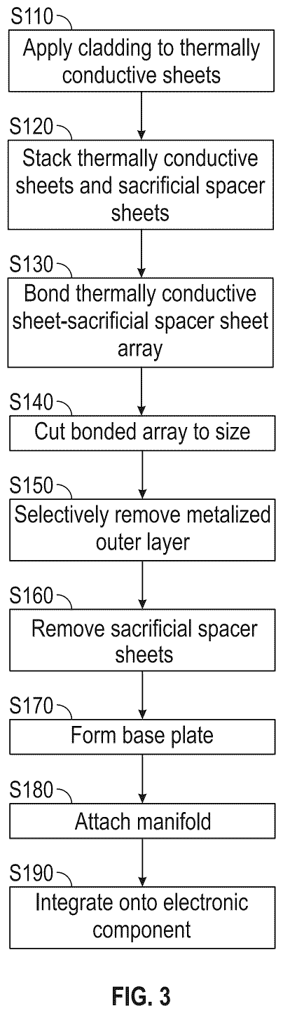

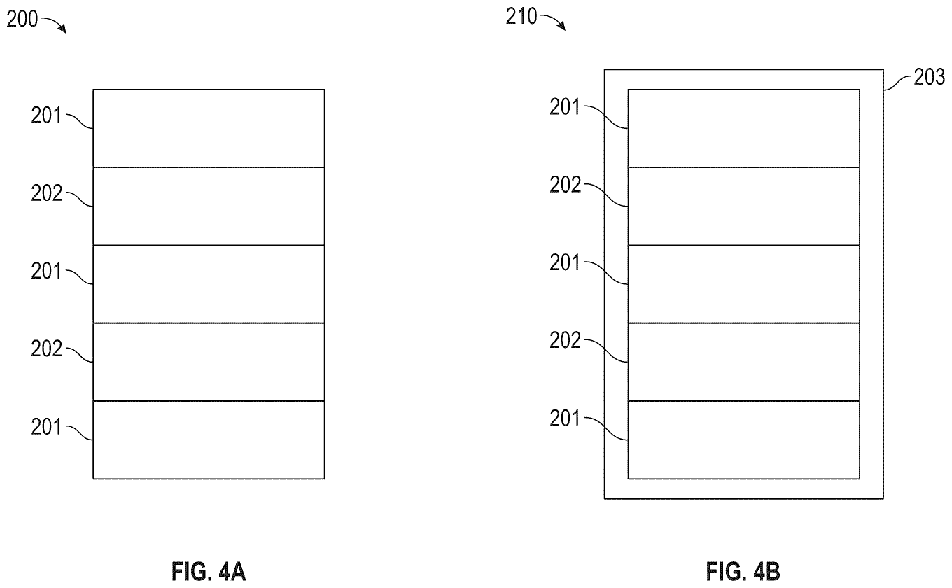

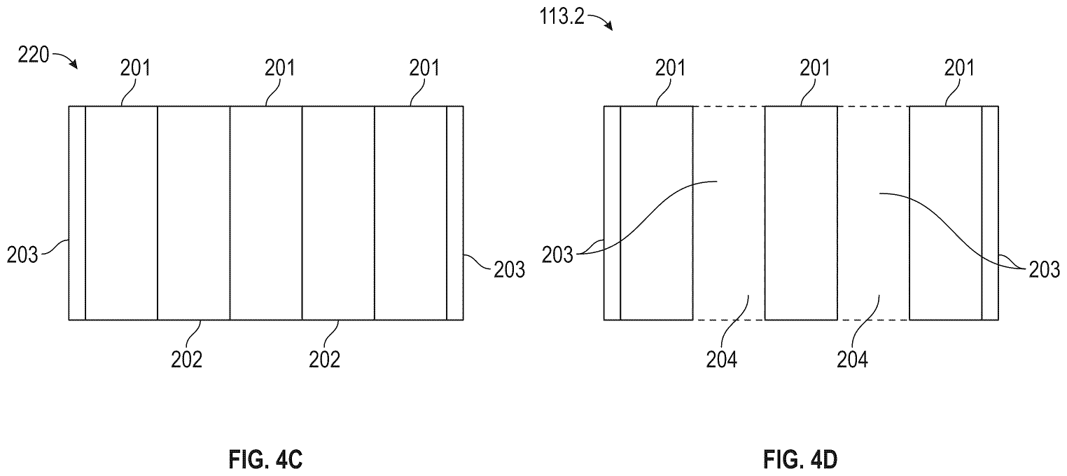

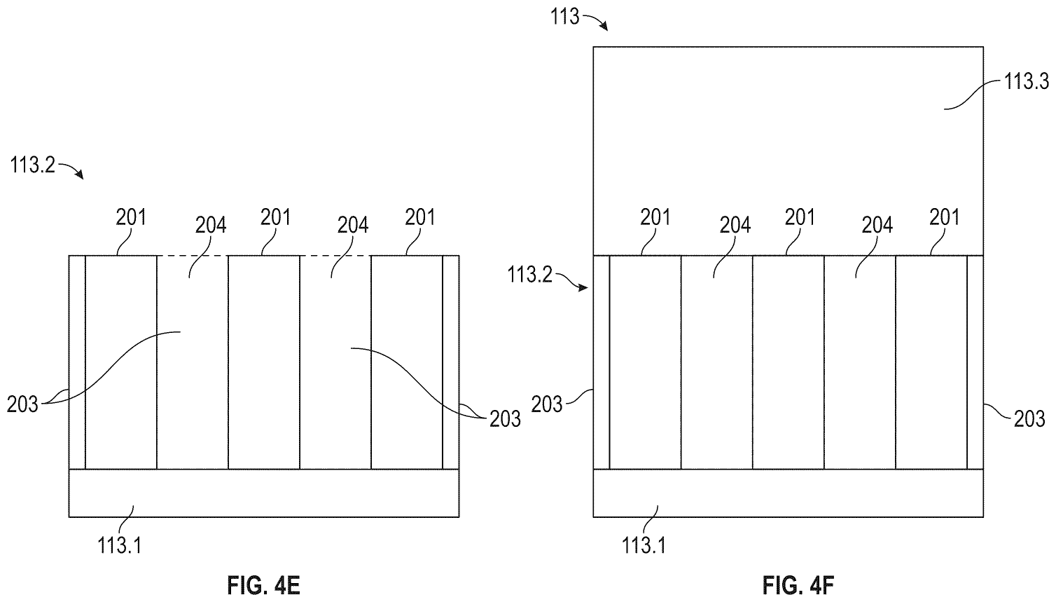

FIG. 3 is a flowchart describing some steps of manufacturing the microchannel cooling block 113 as shown in FIG. 2, and FIGS. 4A-4F illustrate some of the steps described in FIG. 3.

First, a plurality of thermally conductive sheets (or plates) is provided. The thermally conductive sheets may be made of any suitable thermally conductive material, such as graphite, including pyrolytic graphite, aligned pyrolytic graphite, and/or highly ordered pyrolytic graphite, boron nitride, boron arsenide, diamond, silver, copper, gold, silicon carbide, aluminum, aluminum nitride, tungsten, copper-tungsten (CuW), copper-molybdenum (CuMo), molybdenum, graphene, carbon nanotube, boron nitride nanotube, or a boron nitride platelet composite. In some embodiments, an anisotropic material is used as the thermally conductive material.

The material of the thermally conductive sheets, whether it is a type of graphite, boron nitride, or another suitable material, such as those listed above but not limited thereto, should have thermal conductivity of at least 400 W/m-K along its most thermally conductive axis and may have thermal conductivity greater than 800 W/m-K or greater than 1,200 W/m-K along its most thermally conductive axis. For example, one embodiment of the present disclosure uses aligned graphite to form the thermally conductive sheets. Aligned graphite has a thermal conductivity in a range of about 1,000 W/m-K to about 1,500 W/m-K along its most thermally conductive axis (also referred to as its along-fin axis) compared with silicon, which has a thermal conductivity of about 100 W/m-K and copper, which has a thermal conductivity of about 400 W/m-K. Thus, aligned graphite enables higher fin efficiency (e.g., greater than about 50%) for high-aspect ratio fins (e.g., fins having a greater than 30:1 height to thickness ratio).

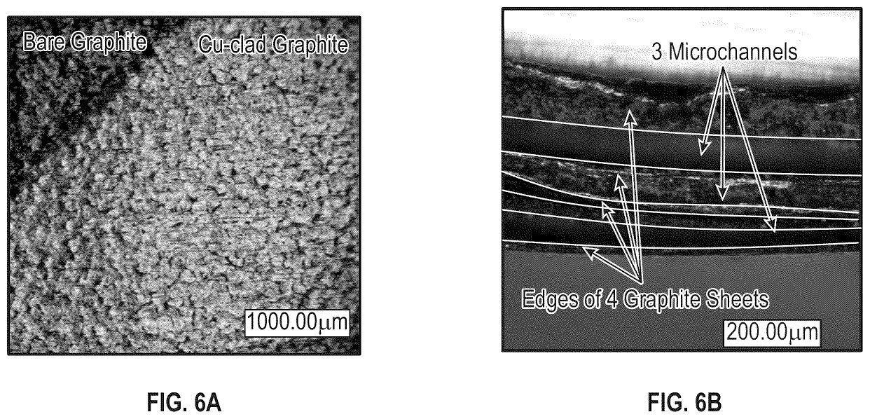

In some embodiments, the thermally conductive sheets may be individually clad by, for example, sputter, evaporating, electroplating, etc., in a heat-transmissive metal, such as copper (Cu), nickel (Ni), or another suitable material having thermal conductivity to clad thermally conductive sheets 201 (S110). In some embodiments, the heat-transmissive metal for cladding the thermally conductive sheets may have isotropic thermal conductivity. In such embodiments, the cladding may have a thickness in a range of about 1 nm to about 20 μm. In some embodiments, the cladding may have a thickness in a range of about 10 nm to about 2 μm. However, in some embodiments, the thermally conductive sheets are not clad in another material. FIG. 6A is a photograph comparing bare graphite thermally conductive sheet (left side) with copper clad graphite thermally conductive sheet (right side). Hereinafter, for convenience of explanation, the thermally conductive sheets 201 should be understood to refer to both clad and unclad thermally conductive sheets. The thermally conductive sheets 201 may have relatively high thermal conductivity, for example, in a range of about 1000 W/m-K to about 1500 W/m-K in plane. The thermally conductive sheets and/or the clad sheets may have a thickness in a range of about 1 μm to about 500 μm, and in some embodiments, may have a thickness in a range of about 15 μm to about 100 μm. The length and width of the thermally conductive sheets 201 is not particularly limited and can be determined based on the size of the electronic component 112 to which the microchannel array is to be bonded.

Then, thermally conductive sheets 201 are stacked with sacrificial spacer sheets 202 between adjacent ones of the thermally conductive sheets 201 to form a thermally conductive sheet-sacrificial spacer sheet array 200 (S120, FIG. 4A). The thermally conductive sheets 201 are aligned so that their highest or second highest thermally conductive axes, or their highest thermally conductive plane, are in the plane of the thermally conductive sheets 201 itself and are arranged parallel with the other thermally conductive sheets 201. The sacrificial spacer sheets 202 may be zinc (Zn) sheets or polylactic acid (PLA) sheets, but the present disclosure is not limited to these examples. The sacrificial spacer sheets 202 can be made of any suitable material that can be removed (e.g., dissolved), as described in more detail below. The sacrificial spacer sheets 202 may have a thickness in a range of about 1 μm to about 500 μm, including a range of about 15 μm to about 100 μm and a range of about 25 μm to about 50 μm. However, the thickness of the sacrificial spacer sheets 202 is not limited thereto, and the thickness of the sacrificial spacer sheets 202 may be selected based on the desired width of the microchannels, to be described later.

In some embodiments, strengthening features may be provided between and connecting adjacent thermally conductive sheets 201. For example, beads or posts formed of the same material as the thermally conductive sheets 201 or as the cladding material (if present), or a different suitable material, may be formed between adjacent thermally conductive sheets to strengthen the thermally conductive sheets after the sacrificial spacer sheets 202 are removed (e.g., dissolved), as described below.

Then, the thermally conductive sheet-sacrificial spacer sheet array 200 is bound (e.g., bonded) together by a low temperature bonding process, such as plating, chemical vapor deposition, etc., which forms a metalized outer structure (or metalized outer layer) 203 encapsulating the thermally conductive sheet-sacrificial spacer sheet array 200 (S130, FIG. 4B). Any metal or alloy thereof may be used to form the metalized outer structure. This binding (e.g., bonding) provides a rigid external structure that ensures stability (e.g., prevents collapse) of the microchannels after the sacrificial spacer sheets 202 are removed, to be described in more detail below. Hereinafter, the thermally conductive sheet-sacrificial spacer sheet array 200 with the metalized outer structure 203 formed thereon may be referred to as a bonded sheet array 210.

However, the present disclosure is not limited to a low temperature bonding process. In other embodiments, the thermally conductive sheet-sacrificial spacer sheet array 200 may be held together mechanically (e.g., by clamping) while the sacrificial spacer sheets 202 are partially etched from one side. In such an embodiment, the partially etched side can then be metallized (e.g., electroplated) to form the baseplate.

In some embodiments, the bonded sheet array 210 is cut to a desired thickness, which will form its final width and length in its intended use, to create separate bonded sheet arrays having dimensions corresponding to that of an electronic component 112 (S140). In such embodiments, an exposed (or cut) surface of the bonded sheet array 210 (e.g., the surface of the bonded sheet array exposing the base material, that is, the material under the cladding, if present, of the thermally conductive sheets), may be bonded to a supporting wall or has another metalized outer structure 203 formed thereon.

As used herein, the thickness of the thermally conductive sheets 201 and sacrificial spacer sheets 202 refers to the dimension in the stacking direction of the thermally conductive sheets 201 and the sacrificial spacer sheets 202. When applied to an electronic component 112, the bonded sheet array 210 is turned on its side such that its thickness during manufacture then becomes its length and/or width dimension.

In some embodiments, a mother array of thermally conductive sheets 201 and sacrificial spacer sheets 202 may be formed and then cut into various sizes (e.g., to corresponding electronic component profiles) to provide multiple smaller arrays to reduce manufacturing costs.

Then, the metalized outer structure 203 can be selectively removed (e.g., machined or etched), if it is not already at a desired and/or consistent thickness, to a consistent thickness and to expose the internal thermally conductive sheet/sacrificial spacer sheet array at two surfaces thereof (e.g., one surface, e.g., a lower surface, for contact with the base plate 113.1, and one surface, e.g., an upper surface, for contact with the manifold 113.3) (S150, FIG. 4C). At this step, the underlying array of thermally conductive sheets 201 and sacrificial spacer sheets 202 may also be cut (or trimmed) so that the final microchannels have a desired height and to ensure that all (or substantially all) of the thermally conductive sheets 201 have the same height (e.g., so that the array of thermally conductive sheets 201 and sacrificial spacer sheets 202 has planar upper and lower surfaces for connections to other components, described below).

In other embodiments, however, the above-described steps may be performed at the same time or in varying orders. For example, in one embodiment, the base plate may be metalized on one side of the mother array and then cut off to form a daughter array with the baseplate. Then, the remaining mother array may be etched back and metallized again to then cut off to form a second daughter array with the baseplate. Such a process could be repeated until the mother substrate is entirely used.

After the metalized outer structure 203 is formed, the sacrificial spacer sheets 202 may be removed (e.g., dissolved) using any suitable material based on the composition of the sacrificial spacer sheets 202, such as a solvent, acid, and/or base (S160, FIG. 4D). For example, the sacrificial spacer sheets 202 may be dissolved by chemical etching using, for example, dilute NaOH, vapor depolymerizing (e.g., heating polylactic acid with an embedded catalyst to decompose it), or burning out. In other words, embodiments of the present disclosure are not limited to how the sacrificial spacer sheets 202 are removed (or dissolved). The specific timing of this step is not limited so long as the thermally conductive sheets 201 are sufficiently supported, for example, by the metalized outer structure 203 or some other structure. Once the sacrificial spacer sheets 202 are dissolved, microchannels 204 are formed at where the sacrificial spacer sheets 202 were previously present. In FIG. 4D, the metalized outer structure 203 indicated by the dashed lines represents the metalized outer structure 203 visible at an end of the microchannels 204. FIG. 6B shows a photograph of adjacent ones of clad graphite sheets with microchannels formed therebetween at where the sacrificial spacer sheets were dissolved. In FIG. 6B, white lines have been added to better show the area of the microchannels.

By dissolving the sacrificial spacer sheets 202, the microchannels 204 are formed between adjacent ones of the thermally conductive sheets 201, thereby forming the microchannel array 113.2. For example, when the sacrificial spacer sheets 202 are completely dissolved, each microchannel 204 has a width that is the same as that of the thickness of the sacrificial spacer sheets 202 dissolved therefrom. For example, each microchannel 204 may have a width in a range of about 1 μm to about 500 μm, including a range of about 15 μm to about 100 μm and a range of about 25 μm to about 50 μm. Thus, the width of the microchannels 204 may be determined (e.g., may be predetermined) by selecting a thickness of the sacrificial spacer sheets 202.

Before or after the sacrificial spacer sheets 202 are dissolved, the base plate 113.1 is attached to an exposed surface of the thermally conductive sheets 201 or the microchannel array 113.2 (S170, FIG. 4E). The thermally conductive sheets 201 are aligned on the base plate 113.1 so that their highest thermally conductive axis extends away from (e.g., in a range of ±45° with respect to) the base plate 113.1. For example, in one embodiment and depending on the material of the thermally conductive sheets 201, the thermally conductive sheets 201 may be aligned such that the highest or second highest thermally conductive axis or the highest thermally conductive plane thereof extends away from the surface of the base plate 113.1 to which the thermally conductive sheets 201 are attached. Further, in some embodiments, the thermally conductive sheets 201 may also be aligned such that the lowest thermally conductive axis or lowest thermally conductive plane thereof extends away from the microchannels 204. As used herein, the phrase “extends away from” means forms an angle in a range of ±45°. However, in some embodiments, “extends away from” can also mean forms an angle in a range of ±30°, ±20°, ±10°, ±5°, or ±1°.

The base plate 113.1 may include a metal, such as copper (Cu), aluminum (Al), or an alloy thereof, or a polymer or may have a biphasic composition. As some examples, the base plate 113.1 may include (or may be formed of) copper-molybdenum (Cu—Mo), copper-tungsten (Cu—W), copper-graphite (Cu-graphite), and copper-diamond (Cu-diamond) compositions. For example, the base plate 113.1 may be attached to the thermally conductive sheets 201 by electroforming or laser depositing copper-molybdenum (Cu—MO) materials to form a Cu-Mo biphasic composition. The copper phase of such a material provides relatively low thermal resistance while the molybdenum phase provides a relatively low coefficient of thermal expansion (CTE). The Cu—Mo materials can be varied (or selected) to match or substantially match CTEs between the base plate 113.1 and the electronic component 112. For example, the base plate 113.1 may have a CTE value between the CTE values of silicon (Si) and aluminum (Al). Such Cu-Mo biphasic materials and manufacturing methods thereof are described in more detail in U.S. patent application Ser. No. 16/784,890, which is incorporated herein in its entirety.

If the sacrificial spacer sheets 202 are not dissolved before attachment of the base plate 113.1, the sacrificial spacer sheets 202 may be dissolved at this step according to the above-described process.

Then, the manifold 113.3 is attached to the other exposed surface of the thermally conductive sheets 201 or the microchannel array 113.2 (S180, FIG. 4F). The manifold 113.3 may be directly printed onto the thermally conductive sheets 201 or the microchannel array 113.2 by, for example, additive manufacturing. In other embodiments, the manifold 113.3 may be manufactured separately and brazed (or soldered) onto the thermally conductive sheets 201 or the microchannel array 113.2 or mechanically or adhesively bonded onto the thermally conductive sheets 201 or the microchannel array 113.2 with, for example, a gasket therebetween. The manifold 113.3 may include copper (Cu), aluminum (Al), or an alloy thereof, may include a polymer, or may be a biphasic composition, such as a Cu—Mo biphasic composition as described above.

Referring to FIG. 2, the manifold 113.3 is shown as being arranged over the microchannel array 113.2 and opposite to the base plate 113.1. The downwardly pointing arrows represent cooling liquid flow to (or into) the microchannel array 113.2 from the secondary heat exchanger 120, and the upwardly pointing arrows represent heated liquid flow from the microchannel array 113.2 to the secondary heat exchanger 120.

The manifold 113.3 may be an architected (or hierarchical) flow manifold 113.3 as described in U.S. patent application Ser. No. 16/930,203 (now U.S. Pat. No. 11,680,756), which is incorporated herein in its entirety. Architecture flow manifolds 113.3 enable compact flow distribution and collection from the microchannel array 113.2 and provides larger total flow cross-sectional area and shorter flow lengths in the relatively higher-pressure loss per unit length microchannels in the microchannel array 113.2.

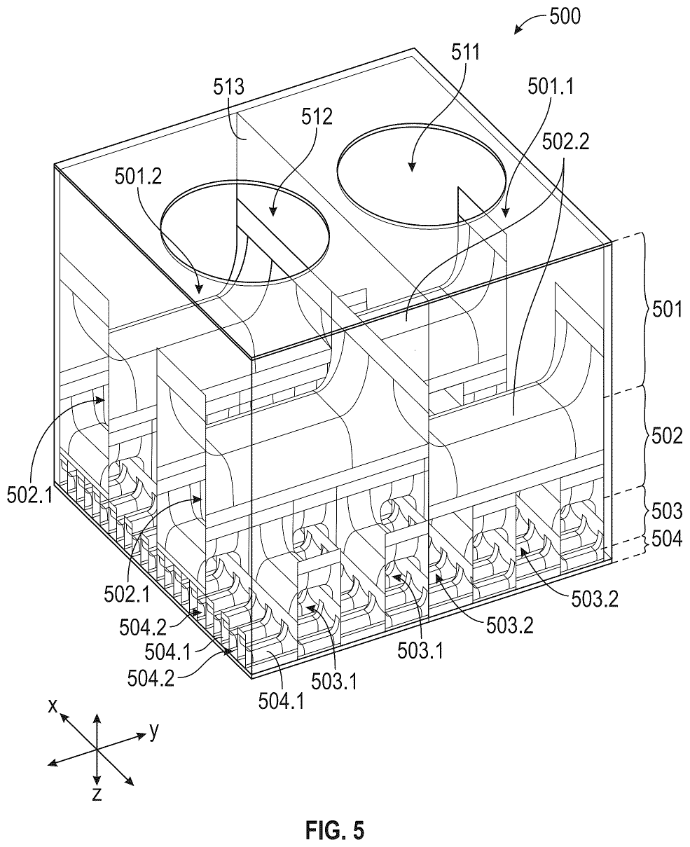

An example of such an architected flow manifold 113.3 is shown in FIG. 5 as the architected flow manifold 500. FIG. 5 is a partial cut-away view of the architected flow manifold 500 with the outer housing in line form. The architected flow manifold 500 includes an inlet 511 and an outlet 512 in an upper wall thereof and a partition wall 513 separating the inlet 511 and the outlet 512 from each other. Thus, the warm and cool fluid (e.g., the fluid coming from the microchannel array 113.2 and the fluid flowing to the microchannel array 113.2) do not mix (e.g., do not physically contact each other) in the heat exchanger; thus, fluid impermeable barriers exist between each interaction of the warm and cool fluid. The fluid impermeable barriers allow for heat transfer between the warm and cool fluids but prevent mixing of the warm and cool fluid.

The architected flow manifold 500 includes a plurality of fluid passages arranged in a plurality of hierarchical levels (e.g., levels that are stacked on each other) 501-504. The architected flow manifold 500 is shown in FIG. 5 as having first-fourth levels 501/502/503/504, but the present disclosure is not limited thereto. In other embodiments, the architected flow manifold 500 may have more or fewer levels depending on the aligned microchannel 113.2 design and/or space requirements, etc.

The first level 501 of the architected flow manifold 500 may be open to the inlet 511 and outlet 512 and may include two open spaces (e.g., two collection volumes). The first level 501 may be considered as having two fluid passages (or two fluid reservoirs), a first fluid passage (or first fluid reservoir) 501.1 in fluid communication with the inlet 511, and a second fluid passage (or second fluid reservoir) 501.2 in fluid communication with the outlet 512.

Each level of the manifold 500 includes the same number or more fluid passages than the preceding level. The number of fluid passages in the levels in the following example embodiments are used as examples to explain the aspects and features of the present disclosure. As such, the number of fluid passages in each level as described below are merely examples and may be suitably varied.

The second level 502 of the architected flow manifold 500 may be in fluid communication with the first level 501 above it and the third level 503 below it. The second level 502 may include four (or more) fluid passages 502.1/502.2, including two first fluid passages 502.1 and two second fluid passages 502.2. The first fluid passages 502.1 are in fluid communication with the first fluid passage 501.1 in the first level 501 (e.g., are in fluid communication with the inlet 511), and the second fluid passages 502.2 are in fluid communication with the second fluid passage 501.2 in the first level 501 (e.g., are in fluid communication with the outlet 512). The first fluid passages 502.1 may extend perpendicularly to (or may extend to cross) the outlet 512 flow direction (e.g., may extend in the y-direction) and may extend under the inlet 511. Similarly, the second fluid passages 502.2 may extend perpendicularly to (or may extend to cross) the inlet 511 flow direction (e.g., may extend in the y-direction) and may extend under the outlet 512. In this way, heat may be transferred between the warm and cool fluid in the manifold 500, increasing the overall heat transfer efficiency of the heat exchanger by improve heat transfer in the manifold 500.

Further, the first fluid passages 502.1 and the second fluid passages 502.2 may be interlaced with each other. For example, the first fluid passages 502.1 may be between two adjacent ones of the second fluid passages 502.2 (e.g., in the x-direction). In the second level 502, for example, ones of the first fluid passages 502.1 are alternatively arranged with ones of the second fluid passages 502.2 in the x-direction. The first and second fluid passages in each of the levels (described further below) except the first level 501 are similarly interlaced with each other within each level.

In some embodiments, the inlet 511 and the outlet 512 may be arranged in different levels from each other. For example, one or more inlets 511 may be arranged in the first level 501, and one or more outlets 512 may be arranged in the second level 502.

The third level 503 of the architected flow manifold 500 may be in fluid communication with the second level 502 above it and the fourth level 504 below it. The third level 503 may include eight fluid passages 503.1/503.2, four first fluid passages 503.1 and four second fluid passages 503.2. Each of the fluid passages 503.1/503.2 in the third level 503 may be about half the size of each of the fluid passages 502.1/502.2 in the second level 502. Each of the first fluid passages 503.1 may be in fluid communication with all (or some or one) of the first fluid passages 502.1, and each of the second fluid passages 503.2 may be in fluid communication with all (or some or one) of the second fluid passages 502.2, thereby improving flow conditions and reducing a pressure drop between the levels. In other embodiments, each of the first fluid passages 503.1 may be in fluid communication with only some or, in some cases, only one, of the first fluid passages 502.1, with the second fluid passages 503.2 having the same or similar configuration.

The fluid passages 503.1/503.2 in the third level 503 may be below and may extend in a direction perpendicular to the extension direction of the fluid passages 502.1/502.2 in the second level 502 (e.g., may extend in the z-direction). By alternating the fluid passage directions between the levels, the manifold 500 may be made more compact. Further, in some embodiments, air gaps may be formed between the warm and cool fluid passages within each level and between levels to decrease heat transfer in the architected flow manifold 500 and to improve heat transfer in the microchannel array 113.2.

The fourth level (e.g., the final level) 504 of the architected flow manifold 500 may be in fluid communication with the third level 503 above it and the microchannel array 113.2 below it. The fourth level 504 may include twenty-four fluid passages 504.1/504.2, twelve first fluid passages 504.1 and twelve second fluid passages 504.2. Each of the fluid passages 504.1/504.2 in the fourth level 504 may be about half the size of each of the fluid passages 503.1/503.2 in the third level 503. However, because there are more fluid passages in the fourth level 504 than in the third level 503, thereby reducing (or minimizing) any change between levels of the total cross-sectional flow area, a pressure drop in the fluids between the levels is reduced and flow is improved. Further, each of the first fluid passages 504.1 may be open to all (or some or one) of the first fluid passages 503.1, and each of the second fluid passages 504.2 may be open to all (or some or one) of the second fluid passages 503.2, thereby improving flow distribution.

While the architected flow manifold 500 is described has having four levels 501-504, the present disclosure is not limited thereto. In other embodiments, the architected flow manifold 500 may include fewer than four levels, such as two or three levels, or more than four levels, such as eight or more, or twenty or more. The number of levels is not limited and may be selected based on overall size constraints.

The outlet arrangement of the fluid passages 504.1/504.2 in the fourth level 504 may correspond to the microchannel array 113.2. For example, fluid passages 504.1/504.2 in the fourth level 504 may primarily extend in the extension direction of the microchannel array 113.2 or perpendicular to the extension direction of the microchannel array 113.2. For example, in FIG. 2, the inlet fluid passages primarily extend in parallel with the extension direction of the microchannel array 113.2 and the outlet fluid passages primarily extend perpendicularly to the extension direction of the microchannel array 113.2. The present disclosure, however, is not limited thereto. In other embodiments, an opposite arrangement is possible, or both the inlet and outlet fluid passages of the architected flow manifold 500 may extend at about a 45° angle with respect to the extension direction of the microchannel array 113.2. Further, the fluid passages 504.1/504.2 in the fourth level 504 may have a length and/or width in a range of 0.1 mm to about 1 cm or, in some embodiments, a range of about 0.3 mm to about 5 mm. Thus, the architected flow manifold 500, across a plurality of levels, separates

the single inlet flow into a plurality of individual flows to better correspond to the microchannel array 113.2. Similarly, the architected flow manifold 500 receives a plurality of individual fluid flows from the microchannel array 113.2 and, across the plurality of levels, and coalesces the fluid into a single outlet flow. Each increasing level 501-504 of the manifold 500 may have smaller fluid passages and/or more fluid passages to separate (or coalesce in the case of the outlet) the fluid flow.

Lastly, the microchannel cooling block 113 is attached to (e.g., integrated with) the electronic component 112 to be cooled (S190). The microchannel cooling block 113 (e.g., the base plate 113.1 thereof) may be soldered or brazed onto the electronic component 112 (e.g., onto an integrated heat spreader of the electronic component 112).

Such integration provides high thermal conductivity and low thermal resistance, for example, less than 0.008 K/W. In some embodiments, reflowable solder may be used to allow for in-field servicing and/or replacement of microchannel cooling blocks 113 or electronic components 112.

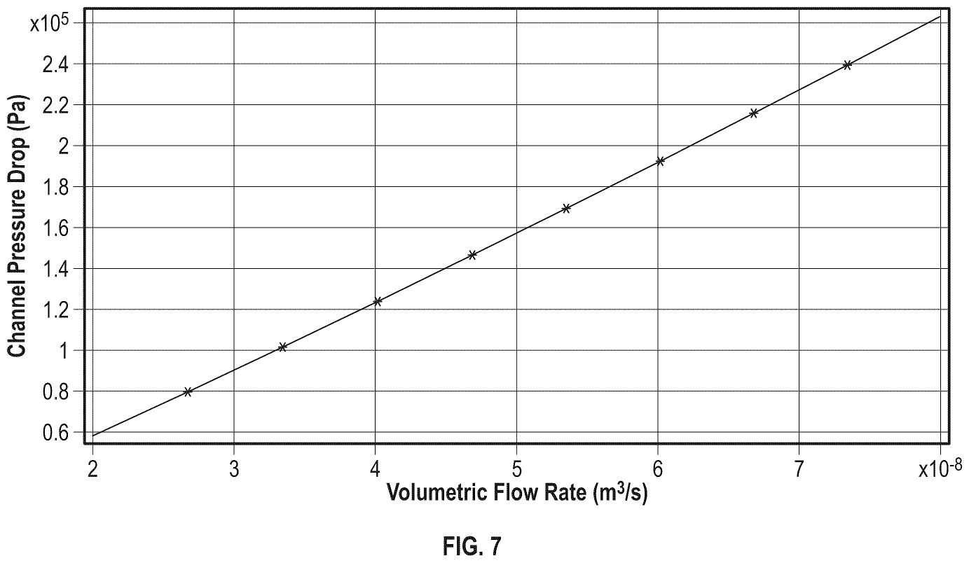

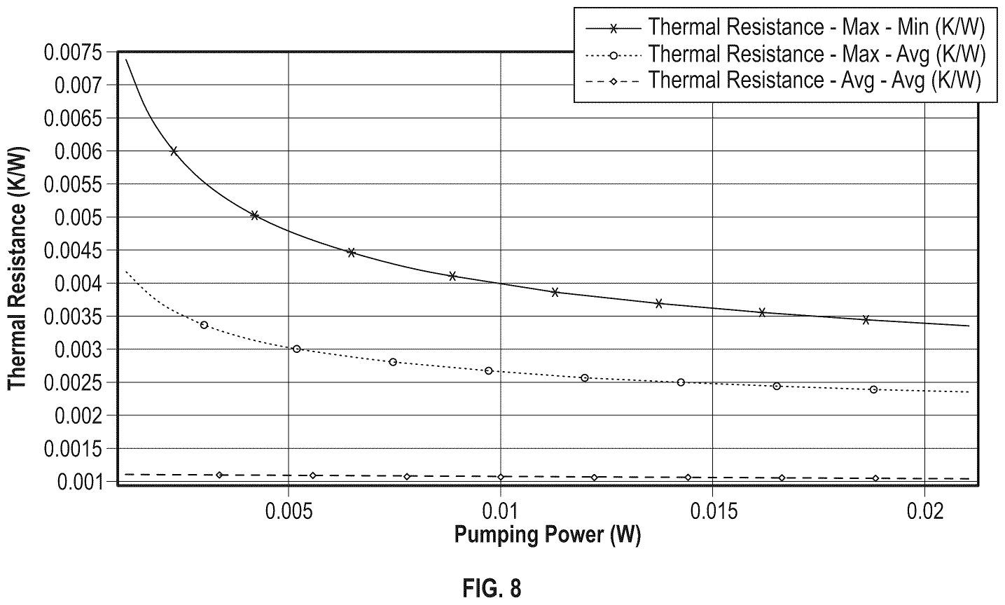

FIG. 7 is a graph showing pressure drop within a microchannel of the microchannel array 113.2 according to an embodiment of the present disclosure as a function of total volumetric flow rate. FIG. 8 is a graphing showing the thermal resistance of the microchannel array 113.2 according to an embodiment of the present disclosure as a function of required pumping power.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Although example embodiments of a microchannel cooling block and a cooling system including the microchannel cooling block have been described and illustrated herein, many modifications and variations within those embodiments will be apparent to those skilled in the art. Accordingly, it is to be understood that a microchannel cooling block and a cooling system including the microchannel cooling block according to the present disclosure may be embodied in forms other than as described herein without departing from the spirit and scope of the present disclosure. The present disclosure is defined by the following claims and equivalents thereof.

What is claimed is:

1. A microchannel cooling block comprising:
a base plate;
a microchannel array comprising a plurality of thermally conductive plates connected to and extending from a surface of the base plate, the thermally conductive plates being aligned so that a highest or second highest thermally conductive axis thereof extends away from the surface of the base plate, adjacent ones of the thermally conductive plates being spaced apart from each other to form a plurality of microchannels between the thermally conductive plates, one of the microchannels being between each adjacent two of the thermally conductive plates; and
a manifold connected to the thermally conductive plates, an interior of the manifold being in fluid communication with the microchannels in the microchannel array.

2. The microchannel cooling block of claim 1, wherein the thermally conductive plates comprise graphite, boron nitride, boron arsenide, diamond, silver, copper, gold, silicon carbide, aluminum, aluminum nitride, tungsten, copper-tungsten (CuW), copper-molybdenum (CuMo), molybdenum, graphene, carbon nanotube, boron nitride nanotube, or a boron nitride platelet composite.

3. The microchannel cooling block of claim 1, wherein one or more of the thermally conductive plates is individually clad with a metal.

4. The microchannel cooling block of claim 1, wherein the thermally conductive plates have a thickness in a range of 1 μm to 500 μm.

5. The microchannel cooling block of claim 1, wherein the microchannels have a width in a range of 1 μm to 500 μm.

6. The microchannel cooling block of claim 1, wherein the base plate comprises copper.

7. The microchannel cooling block of claim 1, wherein the manifold comprises a plurality of levels, each subsequent level having a greater number of fluid flow passages than a preceding level.

8. A cooling system comprising:
an electronic component;
a microchannel cooling block on the electronic component, the microchannel cooling block comprising:
a base plate;
a microchannel array comprising a plurality of thermally conductive plates connected to and extending from the base plate with a plurality of microchannels between the thermally conductive plates, one of the microchannels being between two adjacent ones of the thermally conductive plates; and
a manifold connected to the thermally conductive plates, an interior of the manifold being in fluid communication with the microchannels in the microchannel array; and
a heat exchanger in fluid communication with the manifold of the microchannel cooling block.

9. The cooling system of claim 8, wherein a coolant flowing between the microchannel cooling block and the heat exchanger is water based.

10. The cooling system of claim 8, further comprising a primary heat exchanger,
wherein the heat exchanger is a secondary heat exchanger,
wherein the secondary heat exchanger is configured to transfer heat to the primary heat exchanger.

11. A method of manufacturing a microchannel cooling block, the method comprising:
alternately stacking a plurality of thermally conductive sheets and sacrificial spacer sheets to form a thermally conductive sheet-sacrificial spacer sheet array;
bonding the thermally conductive sheet-sacrificial spacer sheet array together by forming a metalized outer structure around the thermally conductive sheet-sacrificial spacer sheet array;
removing the sacrificial spacer sheets to form a plurality of microchannels between the thermally conductive sheets; and
attaching a base plate to one side of the thermally conductive sheets.

12. The method of claim 11, further comprising individually cladding one or more of the thermally conductive sheets.

13. The method of claim 11, wherein the thermally conductive sheets comprise graphite, boron nitride, boron arsenide, diamond, silver, copper, gold, silicon carbide, aluminum, aluminum nitride, tungsten, copper-tungsten (CuW), copper-molybdenum (CuMo), molybdenum, graphene, carbon nanotube, boron nitride nanotube, or a boron nitride platelet composite.

14. The method of claim 11, further comprising cladding the thermally conductive sheets with a thermally conductive metal.

15. The method of claim 11, wherein the sacrificial spacer sheets are zinc sheets or polylactic acid sheets.

16. The method of claim 11, wherein the attaching of the base plate comprises electroforming a copper material on the one side of the thermally conductive sheets.

17. The method of claim 11, wherein the metalized outer structure comprises copper.

18. The method of claim 11, further comprising attaching a manifold to another side of the thermally conductive sheets.

19. The method of claim 18, wherein the manifold comprises a plurality of levels, each subsequent level having a greater number of fluid flow passages than a preceding level.

20. The method of claim 11, wherein the thermally conductive sheets have a thickness in a range of 1 μm to 500 μm, and wherein the sacrificial spacer sheets have a thickness in a range of 1 μm to 500 μm.
